(19) United States
(12) Patent Application Publication
(10) Pub. No.: US 2026/0156945 A1
(43) Pub. Date: Jun. 4, 2026

(54) SEMICONDUCTOR DEVICE

(71) Applicant: MEDIATEK INC., Hsinchu City (TW)

(72) Inventors: Feng-Yuan LU, Hsinchu City (TW); Yi-Chun TSAI, Hsinchu City (TW); Wei-Min HSU, Hsinchu City (TW); Jen-Hang YANG, Hsinchu City (TW); Shih-Yun LIN, Hsinchu City (TW); Heng-Liang HUANG, Hsinchu City (TW); Yu-Wen TSAI, Hsinchu City (TW)

(21) Appl. No.: 19/404,230

(22) Filed: Dec. 1, 2025

Related U.S. Application Data
(60) Provisional application No. 63/726,679, filed on Dec. 2, 2024.

(51) Int. Cl. H10D 89/10

(52) U.S. Cl. CPC H10D 89/10

(57) ABSTRACT

The semiconductor device includes a first layout area and a second layout area. The first layout area includes a first semiconductor cell region, a second semiconductor cell region, a third semiconductor cell region, and a first boundary cell region. The second semiconductor cell region is configured to be arranged near the first semiconductor cell region along a first direction. The third semiconductor cell region is configured to be arranged near the second semiconductor cell region along a second direction. The first boundary cell region is configured to be arranged around the first semiconductor cell region, the second semiconductor cell region, and third semiconductor cell region. The second layout area includes a hybrid cell region and a second boundary cell region. The second boundary cell region is configured to be arranged along with the hybrid cell region.

### CROSS REFERENCE TO RELATED APPLICATIONS

This Application claims priority of U.S. Provisional Application No. 63/726,679, filed on Dec. 2, 2024, the entirety of which is incorporated by reference herein.

### BACKGROUND OF THE INVENTION

### Field of the Invention

The present invention relates to a semiconductor device, and, in particular, to a semiconductor device for layout design.

### Description of the Related Art

Currently, in semiconductor layouts, boundary cells are present between sub-blocks of fin cells. There is also a spacing between the boundary cells. The excessive use of boundary cells and spacing results in inefficient utilization of layout space.

Therefore, there is a need to develop a semiconductor device capable of reducing such spatial inefficiency.

### BRIEF SUMMARY OF THE INVENTION

An embodiment of the present invention provides a semiconductor device. The semiconductor device includes a first layout area and a second layout area. The first layout area includes a first semiconductor cell region, a second semiconductor cell region, a third semiconductor cell region, and a first boundary cell region. The second semiconductor cell region is configured to be arranged near the first semiconductor cell region along a first direction. The third semiconductor cell region is configured to be arranged near the second semiconductor cell region along a second direction. The first boundary cell region is configured to be arranged around the first semiconductor cell region, the second semiconductor cell region, and third semiconductor cell region. The second layout area includes a hybrid cell region and a second boundary cell region. The second boundary cell is configured to be arranged along with the hybrid cell region.

In one embodiment, the first semiconductor cell region abuts the second semiconductor cell region.

In one embodiment, the second semiconductor cell region abuts the third semiconductor cell region.

In one embodiment, each of the first semiconductor cell region, the second semiconductor cell region, and the third semiconductor cell region comprises a first cell height.

In one embodiment, the hybrid cell region comprises a second cell height and a third cell height. The first cell height, the second cell height, and the third cell height are different from each other.

In one embodiment, each of the first semiconductor cell region, the second semiconductor cell region, and the third semiconductor cell region comprises a first cell type.

In one embodiment, the hybrid cell region comprises a second cell type. The first cell type and the second cell type are different from each other.

In one embodiment, at least two of the first semiconductor cell region, the second semiconductor cell region, and the third semiconductor cell region are configured with substantially the same layout outline.

In one embodiment, the first boundary cell region is absent between the first semiconductor cell region and the second semiconductor cell region. Further, a space is absent between the first semiconductor cell region and the second semiconductor cell region.

In one embodiment, the first boundary cell region is absent between the second semiconductor cell region and the third semiconductor cell region. Further, the space is absent between the second semiconductor cell region and the third semiconductor cell region.

In one embodiment, the first semiconductor cell region and the hybrid cell region are separated by a distance.

An embodiment of the present invention provides a semiconductor device. The semiconductor device includes a first layout area and a second layout area. The first layout area includes a first semiconductor cell region, a second semiconductor cell region, and a first boundary cell region. The second semiconductor cell region is configured to abut the first semiconductor cell region along a first direction. The first boundary cell region is configured to be arranged along with the first semiconductor cell region and the second semiconductor cell region. The second layout area includes a hybrid cell region and a second boundary cell region. The second boundary cell region is configured to be arranged along with the hybrid cell region.

In one embodiment, each of the first semiconductor cell region and the second semiconductor cell region comprises a first cell height.

In one embodiment, the hybrid cell region comprises a second cell height and a third cell height. The second cell height is greater than the third cell height.

In one embodiment, each of the first semiconductor cell region and the second semiconductor cell region comprises a first cell type.

In one embodiment, the hybrid cell region comprises a second cell type. The first cell type and the second cell type are different from each other.

In one embodiment, at least two of the first semiconductor cell region, the second semiconductor cell region, and the third semiconductor cell region are configured with substantially the same layout outline.

In one embodiment, the first boundary cell region is absent between the first semiconductor cell region and the second semiconductor cell region. Further, the space is absent between the first semiconductor cell region and the second semiconductor cell region.

In one embodiment, the first semiconductor cell region and the hybrid cell region are separated by a distance.

In one embodiment, the first cell type comprises the same fin IP cell, the same fin Macro cell, the same fin SRAM cell, or the same fin Mega cell.

Therefore, according to the technical content of the present disclosure, the semiconductor device shown in the embodiment of the present disclosure can achieve the effect of increasing space utilization in the semiconductor layout and design.

Other features and aspects of the present disclosure will become apparent from the following detailed description of exemplary embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a block diagram of a semiconductor device according to one embodiment of the present disclosure.

FIG. 2A is a block diagram of a semiconductor cell of a semiconductor device according to one embodiment of the present disclosure.

FIG. 2B is a block diagram of a hybrid cell of a semiconductor device according to one embodiment of the present disclosure.

FIG. 3 is a structural diagram of a semiconductor device according to one embodiment of the present disclosure.

FIG. 4 is a structural diagram of a semiconductor device according to one embodiment of the present disclosure.

FIG. 5 is a structural diagram of a semiconductor device according to one embodiment of the present disclosure.

### DETAILED DESCRIPTION OF THE INVENTION

Semiconductor device of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that, in the embodiments illustrated below, without departing from the spirit of the present disclosure, components in multiple different embodiments can be replaced, reorganized, and combined to complete other embodiments. Components in various embodiments can be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the Y-axis direction may be a first direction (width direction), the X-axis direction may be a second direction (length direction), the Z-axis direction may be a third direction (thickness/height direction). In some embodiments, the schematic cross-sectional views of the present disclosure are schematic cross-sectional views observing the XZ plane. In some embodiments, the third direction may be a normal direction of the substrate. In some embodiments, the third direction may be a front direction of the semiconductor device.

Fin structures described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

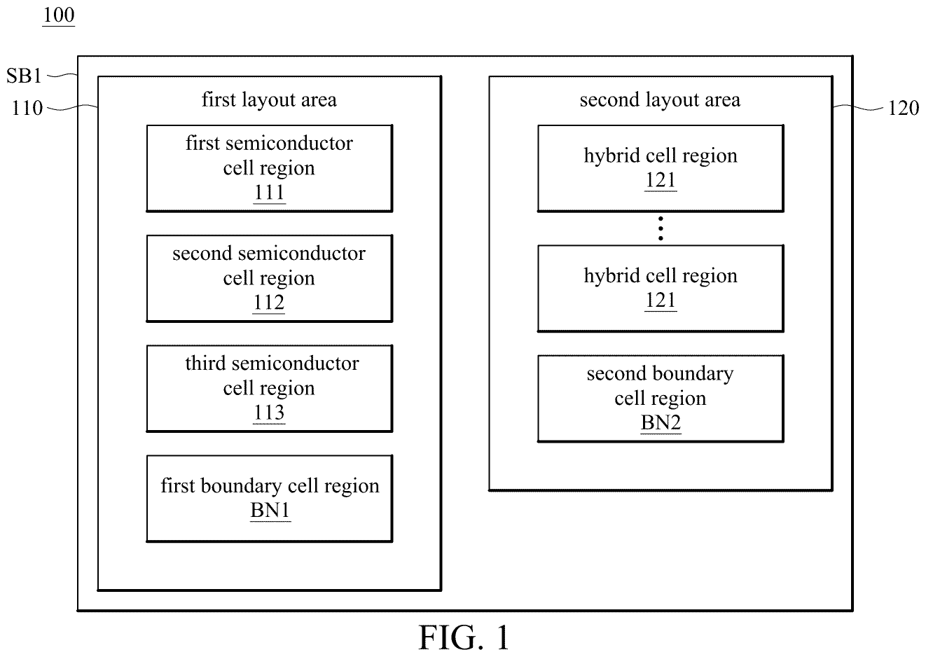

FIG. 1 is a block diagram of a semiconductor device according to one embodiment of the present disclosure. As shown in FIG. 1, in one embodiment, the semiconductor device 100 includes a first layout area 110 and a second layout area 120. The first layout area 110 includes a first semiconductor cell region 111, a second semiconductor cell region 112, a third semiconductor cell region 113, and a first boundary cell region BN1. The second layout area 120 includes a plurality of hybrid cell region 121 and a second boundary cell region BN2.

For example, the first semiconductor cell region 111, the second semiconductor cell region 112, and the third semiconductor cell region 113 may be the same fin cell or the same Gate-all-around (GAA) cell, the first layout area 110 may not overlap the second layout area 120, and there may be one or more hybrid cells 121, but the present disclosure is not limited thereto.

Besides, the semiconductor cells may correspond to sub-blocks of fin cells, the hybrid cell region 121 may correspond to other sub-blocks of fin cells, but the present disclosure is not limited thereto. Furthermore, the first semiconductor cell region 111, the second semiconductor cell region 112, and the third semiconductor cell region 113 are different form the hybrid cell region 121, but the present disclosure is not limited thereto.

In some embodiments, the semiconductor device 100 may include a substrate. The first layout area 110 and the second layout area 120 may arrange on the substrate.

For example, the substrate may be a wafer, the first layout area 110 and the second layout area 120 may deposit on the wafer, but the present disclosure is not limited thereto. Besides, the deposition may be any process that grows, coats, or otherwise transfers a material onto the wafer. The deposition includes the physical vapor deposition (PVD), the chemical vapor deposition (CVD), the electrochemical deposition (ECD), the molecular beam epitaxy (MBE) and more recently, the atomic layer deposition (ALD) among others. Another deposition technology may be the plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

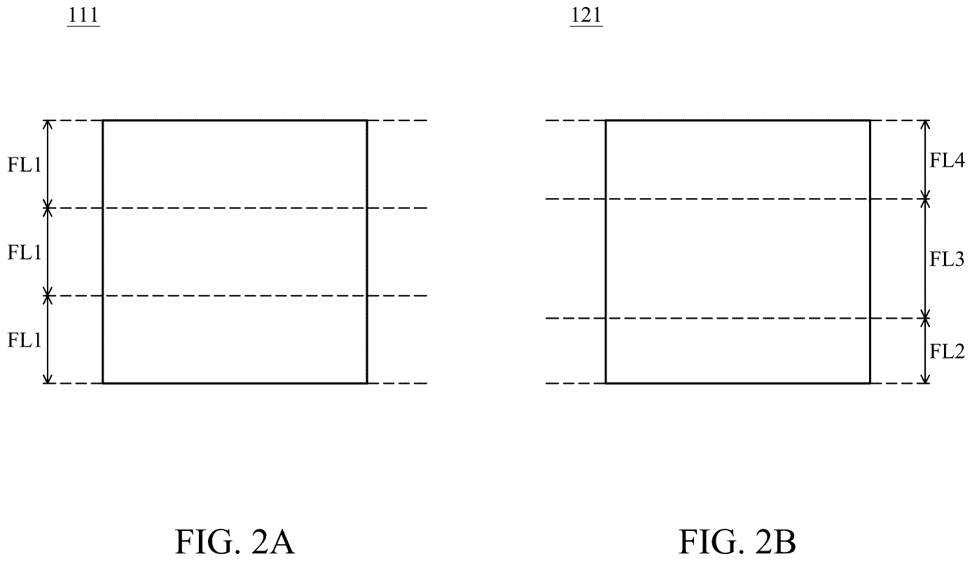

FIG. 2A is a block diagram of a semiconductor cell of a semiconductor device according to one embodiment of the present disclosure. As shown in the FIG. 2A, in one embodiment, the first semiconductor cell region 111 may include a plurality of first cell heights FL1.

For example, the first semiconductor cell region 111 of FIG. 2A may correspond to the first semiconductor cell region 111 of FIG. 1, the length of the first semiconductor cell region 111 along the first direction may be the sum of the first cell heights FL1, but the present disclosure is not limited thereto. In some embodiments, the cell height FL1 may be measured along the first direction (such as the y axis), but the present disclosure is not limited thereto. In some embodiments, the cell height FL1 may be measured along a second direction (such as the x axis), but the present disclosure is not limited thereto.

Please refer to FIG. 1 and FIG. 2A, in one embodiment, each of the first semiconductor cell region 111, the second semiconductor cell region 112, and the third semiconductor cell region 113 comprises the first cell height FL1.

For example, the first semiconductor cell region 111 may have the first cell height FL1, the second semiconductor cell region 112 may have the first cell height FL1, and the third semiconductor cell region 113 may have the first cell height FL1, but the present disclosure is not limited thereto. Furthermore, each of the first semiconductor cell region 111, the second semiconductor cell region 112, and the third semiconductor cell region 113 may have the same cell height, but the present disclosure is not limited thereto.

FIG. 2B is a block diagram of a hybrid cell of a semiconductor device according to one embodiment of the present disclosure. As shown in FIG. 2B, in one embodiment, the hybrid cell region 121 may include a second cell height FL2, a third cell height FL3, and a fourth cell height FL4.

For example, the hybrid cell region 121 of FIG. 2B may correspond to the hybrid cell region 121 of FIG. 1, the third cell height FL3 may greater than the second cell height FL2, and the third cell height FL3 may greater than the fourth cell height FL4, but the present disclosure is not limited thereto.

In some embodiments, each of the second cell height FL2, the third cell height FL3, and the fourth cell height FL4 are different from each other, but the present disclosure is not limited thereto. In some embodiments, the second cell height FL2 may be the same as the fourth cell height FL4, but the present disclosure is not limited thereto.

In some embodiments, the second cell height FL2, the third cell height FL3, and the fourth cell height FL4 may be measured along the first direction (such as the y axis), but the present disclosure is not limited thereto. In some embodiments, the second cell height FL2, the third cell height FL3, and the fourth cell height FL4 may be measured along the second direction (such as the x axis), but the present disclosure is not limited thereto.

Please refer to FIG. 1 to FIG. 2B, in one embodiment, the hybrid cell region 121 may have the second cell height FL2 and the third cell height FL3.

For example, the second cell height FL2 and the third cell height FL3 are different to each other, but the present disclosure is not limited thereto. Furthermore, the hybrid cell region 121 may correspond to a multi-fin cell, but the present disclosure is not limited thereto.

In one embodiment, the first cell height FL1, the second cell height FL2, and the third cell height FL3 are different from each other.

For example, the second cell height and the third cell height may be greater than the first cell height, but the present disclosure is not limited thereto.

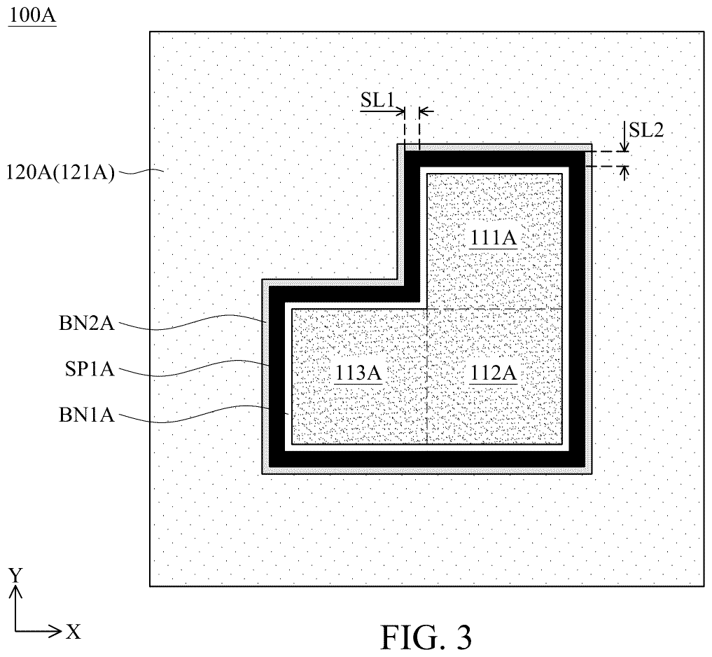

FIG. 3 is a structural diagram of a semiconductor device according to one embodiment of the present disclosure. As shown in FIG. 3, in one embodiment, the semiconductor device 100A includes a first semiconductor cell region 111A, a second semiconductor cell region 112A, a third semiconductor cell region 113A, a first boundary cell region BN1A, a first spacing area SP1A, the hybrid cell region 121A, and the second boundary cell region BN2A. The hybrid cell region 121A and the second boundary cell region BN2A may be arranged in the second layout area 120A.

For example, the first spacing area SP1A may have a first spacing SL1 along the x axis and a second spacing SL2 along the y axis, a value of the second spacing SL2 may be greater than a value of the first spacing SL1, but the present disclosure is not limited thereto.

In some embodiments, the first semiconductor cell region 111A, the second semiconductor cell region 112A, the third semiconductor cell region 113A, the first boundary cell region BN1A, the hybrid cell region 121A, and the second boundary cell region BN2A of FIG. 3 may correspondingly include at least one first semiconductor cell 111, the second semiconductor cell region 112, the third semiconductor cell region 113, the first boundary cell region BN1, the hybrid cell region 121, and the second boundary cell region BN2 of FIG. 1, but the present disclosure is not limited thereto.

In one embodiment, each of the first semiconductor cell region 111A, the second semiconductor cell region 112A, and the third semiconductor cell region 113A comprises a first cell type.

For example, the first cell type may be the same fin Intellectual Property (IP) cell, the same fin Macro cell, the same fin SRAM cell, or the same fin Mega cell, but the present disclosure is not limited thereto.

In one embodiment, the hybrid cell region 121A or the hybrid cell 121 comprises a second cell type. The first cell type and the second cell type are different from each other.

For example, the second cell type may be a multi fin Intellectual Property (IP) cell, a multi fin Macro cell, a multi fin SRAM cell, or a multi fin Mega cell, but the present disclosure is not limited thereto.

In one embodiment, at least two of the first semiconductor cell region 111A, the second semiconductor cell region 112A, and the third semiconductor cell region 113A are configured with substantially the same layout outline.

For example, a layout outline of the first semiconductor cell region 111A may be a rectangle or square, a layout outline of the second semiconductor cell region 112A may be a rectangle or square, a layout outline of the third semiconductor cell region 113A may be a rectangle or square, but the present disclosure is not limited thereto.

In one embodiment, neither the first boundary cell region BN1A nor any spacing is present between the first semiconductor cell region 111A and the second semiconductor cell region 112A.

For example, there may not be a first boundary cell region BN1A between the first semiconductor cell region 111A and the second semiconductor cell region 112A, and there may not be any space between the first semiconductor cell region 111A and the second semiconductor cell region 112A, but the present disclosure is not limited thereto.

In one embodiment, there is not a first boundary cell region BN1A between the second semiconductor cell region 112A and the third semiconductor cell region 113A, and there is also no space between the second semiconductor cell region 112A and the third semiconductor cell region 113A.

For example, there may not be a first boundary cell region BN1A between the second semiconductor cell region 112A and the third semiconductor cell region 113A, and there may not be any space between the second semiconductor cell region 112A and the third semiconductor cell region 113A, but the present disclosure is not limited thereto.

In one embodiment, the first semiconductor cell region 111A and the hybrid cell region 121A are separated by a distance.

For example, the distance may be the first spacing SL1 along the x axis or the second spacing SL2 along the y axis, but the present disclosure is not limited thereto.

In some embodiment, the second semiconductor cell region 112A and the hybrid cell region 121A are separated by the distance, but the present disclosure is not limited thereto. In some embodiment, the third semiconductor cell region 113A and the hybrid cell region 121A are separated by the distance, but the present disclosure is not limited thereto.

Please refer to FIG. 1 and FIG. 3, in one embodiment, the second semiconductor cell region 112 or cell region 112A is configured to be arranged near the first semiconductor cell region 111 or cell region 111A along the first direction (such as the y axis). The third semiconductor cell region 113 or cell region 113A is configured to be arranged near the second semiconductor cell region 112 or cell region 112A along the second direction (such as the x axis). The first boundary cell region BN1 or cell region BN1A is configured to be arranged around (or surround) the first semiconductor cell region 111 or cell region 111A, the second semiconductor cell region 112 or cell region 112A, and the third semiconductor cell region 113 or cell region 113A.

For example, there may not be a first boundary cell region BN1 or cell region BN1A between the first semiconductor cell region 111 or cell region 111A and the second semiconductor cell region 112 or cell region 112A, and there may not be a first boundary cell region BN1 or cell region BN1A between the second semiconductor cell region 112 or cell region 112A and the third semiconductor cell region 113 or cell region 113A, but the present disclosure is not limited thereto.

In one embodiment, the second layout area has the hybrid cell 121 or cell region 121A and the second boundary cell region BN2 or cell region BN2A. The second boundary cell region BN2 or cell region BN2A is configured to be arranged along with the hybrid cell region 121 or cell region 121A.

For example, the second boundary cell region BN2 or cell region BN2A may be arranged around (or surround) the hybrid cell region 121 or cell region 121A, but the present disclosure is not limited thereto.

In one embodiment, the first semiconductor cell region 111 or cell region 111A abuts the second semiconductor cell region 112 or cell region 112A.

For example, there may be no spacing or gap between the first semiconductor cell region 111 or cell region 111A and the second semiconductor cell region 112 or cell region 112A, but the present disclosure is not limited thereto.

In one embodiment, the second semiconductor cell region 112 or cell region 112A abuts the third semiconductor cell region 113 or cell region 113A.

For example, there may be no spacing or gap between the second semiconductor cell region 112 or cell region 112A and the third semiconductor cell region 113 or cell region 113A, but the present disclosure is not limited thereto.

In some embodiments, the length of the first boundary cell region BN1 or cell region BN1A along the first direction (such as the x axis) may be greater than the length of the first boundary cell region BN1 or cell region BN1A along the first direction (such as the y axis). In some embodiments, the length of the second boundary cell region BN2 or cell region BN2A along the first direction (such as the x axis) may be greater than the length of the second boundary cell region BN2 or cell region BN2A along the first direction (such as the y axis).

In some embodiments, the first spacing SL1 may be greater than the length of the first boundary cell region BN1 or cell region BN1A along the first direction (such as the x axis) or the length of the second boundary cell region BN2 or cell region BN2A along the first direction (such as the x axis). In some embodiments, the second spacing SL2 may be greater than the length of the first boundary cell region BN1 or cell region BN1A along the first direction (such as the y axis) or the length of the second boundary cell region BN2 or cell region BN2A along the first direction (such as the y axis).

For example, the first spacing SL1 and the second spacing SL2 may fit the Calibre Physical Verification base rules, but the present disclosure is not limited thereto.

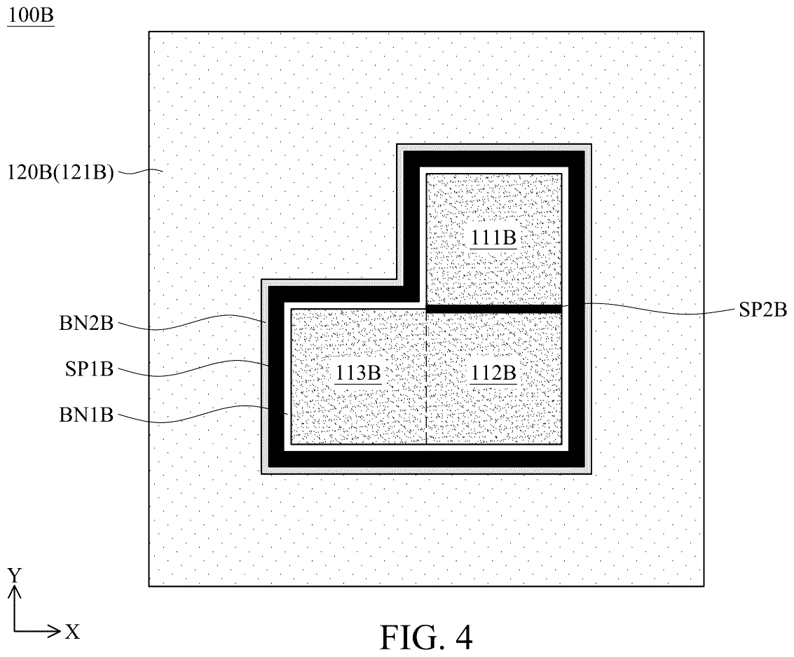

FIG. 4 is a structural diagram of a semiconductor device according to one embodiment of the present disclosure. As shown in FIG. 4, in one embodiment, the semiconductor device 100B includes the first semiconductor cell region 111B, the second semiconductor cell region 112B, the third semiconductor cell region 113B, the first boundary cell region BN1A, the first spacing area SP1B, a second spacing area SP2B, the hybrid cell region 121B, and the second boundary cell region BN2B. The hybrid cell region 121B and the second boundary cell region BN2B may be arranged in the second layout area 120B.

In some embodiments, the first semiconductor cell region 111B, the second semiconductor cell region 112B, the third semiconductor cell region 113B, the first boundary cell region BN1B, the first spacing area SP1B, the hybrid cell region 121B, and the second boundary cell region BN2B of FIG. 4 may correspond to the first semiconductor cell region 111A, the second semiconductor cell region 112A, the third semiconductor cell region 113A, the first boundary cell region BN1A, the first spacing area SP1A, the hybrid cell region 121A, and the second boundary cell region BN2A of FIG. 3, but the present disclosure is not limited thereto.

It must be specifically stated that there may have the second spacing area SP2B between the first semiconductor cell region 111B and the second semiconductor cell region 112B. The existence of the second spacing area SP2B between the first semiconductor cell region 111B and the second semiconductor region 112B may be beneficial for base layer DRC (Design Rule Check) violation prevention. During layout process, dummy fins or dummy GAA fins may be arranged into the spacing area to prevent DRC violation. Also, in certain embodiments where metal routing requirements are higher between two cell regions (for instance, between the first semiconductor cell region 111B and the second semiconductor region 112B like in FIG. 4), the spacing like the second spacing area SP2B creates additional metal routing resources at the metal layers above to facilitate such requirement.

For example, there may not be a first boundary cell region BN1B between the first semiconductor cell region 111B and the second spacing area SP2B, and there may not be a first boundary cell region BN1B between the second spacing area SP2B and the second semiconductor cell region 112B, but the present disclosure is not limited thereto.

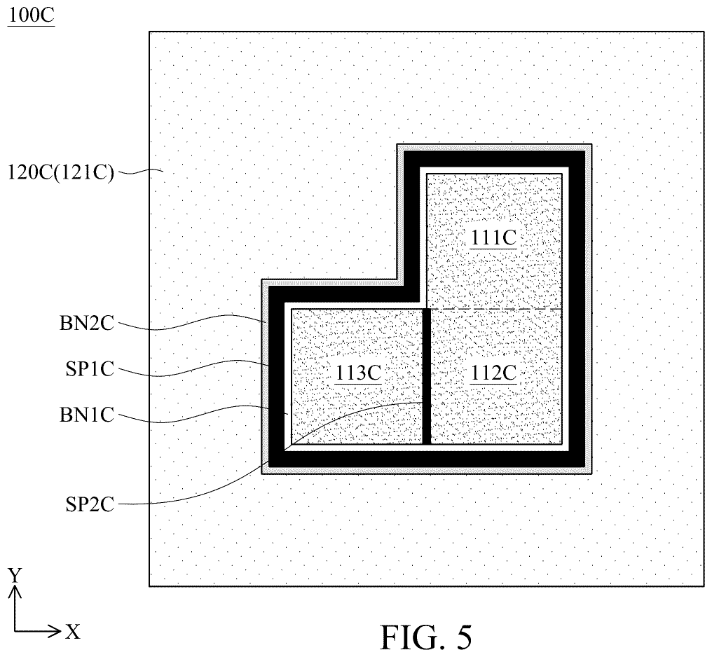

FIG. 5 is a structural diagram of a semiconductor device according to one embodiment of the present disclosure. As shown in FIG. 5, in one embodiment, the semiconductor device 100C includes the first semiconductor cell region 111C, the second semiconductor cell region 112C, the third semiconductor cell region 113C, the first boundary cell region BN1C, the first spacing area SP1C, the second spacing area SP2C, the hybrid cell region 121C, and the second boundary cell region BN2C. The hybrid cell region 121C and the second boundary cell region BN2C may be arranged in the second layout area 120C.

In some embodiments, the first semiconductor cell region 111C, the second semiconductor cell region 112C, the third semiconductor cell region 113C, the first boundary cell region BN1C, the first spacing area SP1C, the hybrid cell region 121C, and the second boundary cell region BN2C of FIG. 5 may correspond to the first semiconductor cell region 111A, the second semiconductor cell region 112A, the third semiconductor cell region 113A, the first boundary cell region BN1A, the first spacing area SP1A, the hybrid cell region 121A, and the second boundary cell region BN2A of FIG. 3, but the present disclosure is not limited thereto.

It must be specifically stated that there may have the second spacing area SP2C between the second semiconductor cell region 112C and the third semiconductor cell region 113C. The second spacing area SP2C may have similar advantages as those of the second spacing area SP2B as previously described.

For example, there may not be a first boundary cell region BN1B between the second semiconductor cell region 112C and the second spacing area SP2C, and there may not be a first boundary cell region BN1B between the second spacing area SP2C and the third semiconductor cell region 113C, but the present disclosure is not limited thereto.

Please refer to FIG. 1 (to FIG. 5), in one embodiment, the semiconductor device 100 may have the first layout area 110 and the second layout area 120. The first layout area 110 may have the first semiconductor cell region 111, the second semiconductor cell region 112, and the first boundary cell region BN1. The second semiconductor cell region 120 is configured to abut the first semiconductor cell region 111 along a first direction (such as y axis). The first boundary cell region BN1 is configured to be arranged along with the first semiconductor cell region 111 and the second semiconductor cell region 112. The second layout area 120 may have the hybrid cell region 121 and the second boundary cell region BN2. The second boundary cell region BN2 is configured to be arranged along with the hybrid cell region 121.

In one embodiment, each of the first semiconductor cell region 111 or cell region 111C and the second semiconductor cell region 112 or cell region 112C comprises the first cell height.

In one embodiment, the hybrid cell region 121 or cell region 121C comprises the second cell height and the third cell height. The second cell height is greater than the third cell height.

In one embodiment, each of the first semiconductor cell region 111 or cell region 111C and the second semiconductor cell region 112 or cell region 112C comprises the first cell type.

In one embodiment, the hybrid cell region 121 or cell region 121C comprises the second cell type. The first cell type and the second cell type are different from each other.

In one embodiment, the first semiconductor cell region 111 or cell region 111C and the second semiconductor cell region 112 or cell region 112C are configured with substantially the same layout outline.

In one embodiment, there is no first boundary cell region BN1 or cell region BN1C, nor is there any space, between the first semiconductor cell region 111 or cell region 111C and the second semiconductor cell region 112 or cell region 112C.

In one embodiment, the first semiconductor cell region 111 or cell region 111C and the hybrid cell region 121 or cell region 121C are separated by a distance.

In one embodiment, the first cell type comprises the same fin IP cell, the same fin Macro cell, the same fin SRAM cell, or the same fin Mega cell.

Generally speaking, a tool for layout design (such as EDA APR tools) may not natively support the use of both a multi-fin site row/std cell and the same fin site row/std cell in the same APR design. An ordinary semiconductor device may have one the spacing area and two the boundary cells (between the plurality of semiconductor cells) in the horizontal direction, the ordinary semiconductor device may also have one the spacing area and two the boundary cells (between the plurality of semiconductor cells) in the vertical direction. The excessive use of boundary cells and spacing results in inefficient utilization of layout space.

However, the semiconductor device 100 may be optimized with respect to spatial utilization. The semiconductor device 100 may be designed without the boundary cells and the spacing area (that is, the empty spacing area) between the plurality of semiconductor cells.

In some embodiments, the same fin IP/Macro/SRAM/Mega cell, but without the same fin boundary cell, is used in each block level frame edge. The same traditional fin site row is added in a multi-fin APR tech-file, using the same fin boundary cells in a multi-fin design. Putting together and grouping the same fin IP/Macro/SRAM/Mega cells to align with the edge reduces the redundant area in between the same fin IP/Macro/SRAM/Mega cells. Both of the same fin and multi-fin pair of boundary cells are used to surround all of the same fin IP/Macro/SRAM/Mega cells after the floorplan adopts the multi-fin design.

For example, the processor of a computer may perform the above layout design steps, but the present disclosure is not limited thereto.

In some embodiments, the same fin IP/Macro/SRAM/Mega cells are integrated into the multi-fin design, albeit without any boundary cells between the same fin IP/Macro/SRAM/Mega cells in the horizontal and vertical directions.

Therefore, according to the technical content of the present disclosure, the semiconductor device shown in the embodiment of the present disclosure can achieve the effect of increasing space utilization in the semiconductor layout and design.

Furthermore, the semiconductor device 100 to 100C shown in the embodiment can be optimized with respect to spatial utilization.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first layout area, comprising:
a first semiconductor cell region;
a second semiconductor cell region, configured to be arranged near the first semiconductor cell region along a first direction;
a third semiconductor cell region, configured to be arranged near the second semiconductor cell region along a second direction;
a first boundary cell region, configured to be arranged around the first semiconductor cell region, the second semiconductor cell region, and the third semiconductor cell region;
a second layout area, comprising:
a hybrid cell region; and
a second boundary cell region, configured to be arranged along with the hybrid cell region.

2. The semiconductor device as claimed in claim 1, wherein
the first semiconductor cell region abuts the second semiconductor cell region.

3. The semiconductor device as claimed in claim 2, wherein
the second semiconductor cell region abuts the third semiconductor cell region.

4. The semiconductor device as claimed in claim 1, wherein
each of the first semiconductor cell region, the second semiconductor cell region, and the third semiconductor cell region comprises a first cell height.

5. The semiconductor device as claimed in claim 4, wherein
the hybrid cell region comprises a second cell height and a third cell height;
wherein the first cell height, the second cell height, and the third cell height are different from each other.

6. The semiconductor device as claimed in claim 1, wherein
each of the first semiconductor cell region, the second semiconductor cell region, and the third semiconductor cell region comprises a first cell type.

7. The semiconductor device as claimed in claim 6, wherein
the hybrid cell region comprises a second cell type;
wherein the first cell type and the second cell type are different from each other.

8. The semiconductor device as claimed in claim 1, wherein
at least two of the first semiconductor cell region, the second semiconductor cell region, and the third semiconductor cell region are configured with substantially a same layout outline.

9. The semiconductor device as claimed in claim 1, wherein
the first boundary cell region is absent between the first semiconductor cell region and the second semiconductor cell region;
wherein a space is absent between the first semiconductor cell region and the second semiconductor cell region.

10. The semiconductor device as claimed in claim 9, wherein
the first boundary cell region is absent between the second semiconductor cell region and the third semiconductor cell region;
wherein the space is absent between the second semiconductor cell region and the third semiconductor cell region.

11. The semiconductor device as claimed in claim 1, wherein
the first semiconductor cell region and the hybrid cell region are separated by a distance.

12. A semiconductor device, comprising:
a first layout area, comprising:
a first semiconductor cell region;
a second semiconductor cell region, configured to abut the first semiconductor cell region along a first direction;
a first boundary cell region, configured to be arranged along with the first semiconductor cell region and the second semiconductor cell region;
a second layout area, comprising:
a hybrid cell region; and
a second boundary cell region, configured to be arranged along with the hybrid cell region.

13. The semiconductor device as claimed in claim 12, wherein
each of the first semiconductor cell region and the second semiconductor cell region comprises a first cell height.

14. The semiconductor device as claimed in claim 13, wherein
the hybrid cell region comprises a second cell height and a third cell height;
wherein the second cell height is greater than the third cell height.

15. The semiconductor device as claimed in claim 12, wherein
each of the first semiconductor cell region and the second semiconductor cell region comprises a first cell type.

16. The semiconductor device as claimed in claim 15, wherein
the hybrid cell region comprises a second cell type;
wherein the first cell type and the second cell type are different from each other.

17. The semiconductor device as claimed in claim 12, wherein
at least two of the first semiconductor cell region and the second semiconductor cell region are configured with substantially a same layout outline.

18. The semiconductor device as claimed in claim 12, wherein
the first boundary cell region is absent between the first semiconductor cell region and the second semiconductor cell region;
wherein a space is absent between the first semiconductor cell region and the second semiconductor cell region.

19. The semiconductor device as claimed in claim 12, wherein
the first semiconductor cell region and the hybrid cell region are separated by a distance.

20. The semiconductor device as claimed in claim 16, wherein
the first cell type comprises one of a same fin IP cell, a same fin Macro cell, a same fin SRAM cell, and a same fin Mega cell.
